(19) United States
(12) Patent Application Publication
(10) Pub. No.: US 2002/0106580 A1
(43) Pub. Date: Aug. 8, 2002

(54) Method for forming a hole-patterned photoresist layer

(76) Inventors: Kazuyuki Nitta, Ebina-shi (JP); Satoshi Shimatani, Yokohama-shi (JP); Kazufumi Sato, Sagamihara-shi (JP)

Correspondence Address: WENDEROTH, LIND & PONACK, L.L.P., 2033 K STREET N. W., SUITE 800, WASHINGTON, DC, 20006-1021, US

(21) Appl. No.: 09/987,718

(22) Filed: Nov. 15, 2001

(30) Foreign Application Priority Data
Nov. 20, 2000 (JP) 2000-353509

(51) Int. Cl. G03F 7/004; G03F 7/26

(52) U.S. Cl. 430/270.1; 430/322; 430/326; 430/396; 430/330

(57) ABSTRACT

The invention discloses a photolithographic patterning method of a photoresist layer for the formation of a patterned resist layer on a substrate surface having a fine hole pattern. The inventive method comprises the steps of forming a patterned resist layer by using a specific chemical-amplification positive-working photoresist composition compounded with a di- or polyvinyloxy compound such as cyclohexanedimethonol divinyl ether as a crosslinking agent of the resinous ingredient and subjecting the patterned resist layer on the substrate to a heat treatment for the so-called thermal flow treatment to effect pattern size reduction of the resist pattern.

### BACKGROUND OF THE INVENTION

The present invention relates to a method for the formation of a finely hole-patterned photoresist layer on a substrate surface or, more particularly, to a method for the formation of a hole-patterned photoresist layer by the application of the photolithographic process by the use of a halftone phase-shift photomask and by the application of the so-called thermal flow process.

As is well known, the photolithographic process for patterning of a resist layer by utilizing actinic rays is widely employed in the manufacture of various kinds of fine electronic devices such as semiconductor devices, e.g., ICs and LSIs, and liquid crystal devices, e.g., LCDs. It is also known that the pattern resolution in the photolithographic patterning process largely depends on the wavelength of the radiation used for patterning light-exposure and the numerical aperture (NA) of the optical system in the light-projection exposure machine.

Along with the trend in the electronic technology of recent years toward more and more increased fineness of the electronic devices, a remarkable shift is noted in the wavelength of the patterning exposure light toward shorter and shorter wavelengths from the traditional i-line light of 365 nm wavelength to the KrF excimer laser beams of 248 nm wavelength further to the ArF excimer laser beams of 193 nm wavelength as accompanied by a development work to design a projection exposure machine having an optical system with an increased numerical aperture. Designing of an optical system with an increased numerical aperture, however, is not without a problem due to a decrease in the pattern resolution because an increase in the numerical aperture of an optical system is necessarily accompanied by a decrease in the focusing depth latitude.

The so-called phase-shift method is known in the prior art as one of the methods for improving the patterning resolution without modifying the numerical aperture of the optical projection system. For example, a proposal is already made in Japanese Patent Kokai No. 11-15151 on a method for the formation of a contact hole pattern as an application of the phase-shift method.

In the phase-shift method, a thin film of a transparent material, which serves to shift the phase of the exposure light and referred to as a shifter hereinafter, is formed on localized areas of a photomask and the interference of the phase-shifted light by passing through the shifter and the light not passing through the shifter without a phase shift is utilized to improve the patterning resolution. Among a variety of phase-shift photomasks proposed heretofore, the so-called halftone phase-shift photomask is considered to be the most promising from the standpoint of practical applications.

When a hole-patterned resist layer is formed by using the halftone phase-shift photomask, however, it is sometimes the case that a subpattern of the light called sidelobe is caused around the main pattern resulting in occurrence of recesses called dimples around the resist hole to decrease fidelity of patterning. This is one of the serious problems to be solved in the practical application of the phase-shift method.

As a means for accomplishing further fineness of resist patterning in the photolithographic technology, on the other hand, the thermal flow process has become highlighted in recent years. In this process, a photoresist layer is subjected to patternwise light exposure and development treatment and the thus obtained resist pattern is subjected to a heating treatment to cause thermal flow so that a resist pattern obtained has reduced dimensions of the resist pattern as compared with the dimensions just as developed.

While the thermal flow process has an advantage that the photoresist composition used therein can be a readily available product, it is essential in the use of a conventional photoresist composition to exactly control the amount of pattern size reduction per unit change of the temperature as a consequence of the principle of the method to effect flow of the resist pattern as developed by heating. This means that the photoresist composition must have properties to meet the requirement so that it is rather a difficult matter to obtain an optimum photoresist composition among conventional chemical-amplification photoresist compositions.

### SUMMARY OF THE INVENTION

The present invention accordingly has an object to provide a method, in the photolithographic formation of a resist hole pattern by using a halftone phase-shift photomask, capable of suppressing occurrence of dimples caused in the use of the above-mentioned halftone phase-shift photomask and exactly controlling the amount of pattern size reduction per unit change of the temperature in the application of the thermal flow process.

Thus, the present invention provides a method for the formation of a fine resist hole pattern, in conducting photolithographic formation of a resist hole pattern by using a halftone phase-shift photomask, which comprises the steps of:

(1) forming a photoresist layer on the surface of a substrate by using a positive-working photoresist composition comprising

(A) a resinous compound capable of being imparted with increased solubility in alkali by interacting with an acid,

(B) a compound capable of generating an acid by irradiation with a radiation, (C) a compound having, in a molecule, at least two vinyloxy groups which react with the component (A) to form crosslinks, and (D) an organic amine compound;

(2) patternwise exposing the photoresist layer to light through a halftone phase-shift photomask;

(3) developing the photoresist layer to form a patterned resist layer; and

(4) heating the patterned resist layer to cause reduction of the resist pattern size.

Further, a positive-working photoresist composition provided by the present invention comprises, as a uniform solution in an organic solvent;

(A) 100 parts by weight of a resinous compound capable of being imparted with increased solubility in an aqueous alkaline solution by interacting with an acid;

(B) from 1 to 20 parts by weight of a compound capable of generating an acid by irradiation with a radiation;

(C) from 0.1 to 25 parts by weight of a compound having, in a molecule, at least two vinyloxy groups which react with the component (A) to form crosslinks; and

(D) from 0.01 to 1 part by weight of an organic amine compound.

### DETAILED DESCRIPTION OF THE PREFERRED EMBODIMENTS

As is described above, the positive-working photoresist composition used in step (1) of the inventive method comprises (A) a resinous compound capable of being imparted with increased solubility in alkali by interacting with an acid, (B) a compound capable of generating an acid by irradiation with a radiation, (C) a compound having, in a molecule, at least two vinyl ether groups, i.e. vinyloxy groups, which react with the component (A) to form crosslinks and (D) an organic amine compound.

Examples of the resinous compound as the component (A) which can be imparted with increased solubility in alkali by interacting with an acid include hydroxystyrene-based copolymers comprising hydroxystyrene units substituted by acid-dissociable solubility-reducing groups for the hydrogen atoms of the hydroxyl groups and copolymers comprising (meth)acrylic acid units substituted by acid-dissociable groups for the hydrogen atoms of the carboxyl groups and hydroxystyrene units, which are known resins currently under use as the resinous ingredient in a positive-working photoresist composition for exposure with KrF excimer laser beams, and resins without aromaticity having polycyclic hydrocarbon groups with an acid dissociable group, which are known as a resinous ingredient in a positive-working photoresist composition for exposure with ArF excimer laser beams, of which a particularly preferable resinous compound for a resist composition of KrF excimer laser beam exposure suitable for low-temperature baking is a hydroxystyrene-based copolymer of which the hydroxystyrene units, which can be hydroxy-α-methylstyrene units, are partly substituted by acid-dissociable groups for the hydroxyl hydrogen atoms.

The above mentioned hydroxystyrene units or hydroxy-α-methylstyrene units substituted by acid-dissociable solubility-reducing groups for the hydroxyl hydrogen atoms have an effect that, when the photoresist layer is irradiated with a radiation, the acid-dissociable groups are removed by dissociation to regenerate the phenolic hydroxyl groups so that the resin which is insoluble in alkali before light-exposure is rendered alkali-soluble by the light-exposure. The isomeric position of the hydroxyl groups on the benzene rings can be any of the o-, m- and p-positions of which the p-position is preferable in respect of good availability of the corresponding hydroxystyrene monomer.

The above mentioned acid-dissociable solubility-reducing group is not particularly limitative and can be any of those of the resinous ingredients in the chemical-amplification photoresist compositions for exposure with KrF or ArF excimer laser beams including tert-alkyloxycarbonyl groups, tert-alkyloxycarbonylalkyl groups, tert-alkyl groups, cyclic ether groups, alkoxyalkyl groups, 1-alkyl monocycloalkyl groups and 2-alkyl polycycloalkyl groups as examples of preferable ones.

The tert-alkyloxycarbonyl group is exemplified by tert-butyloxycarbonyl and tert-amyloxycarbonyl groups. The tert-alkyloxycarbonylalkyl group is exemplified by tert-butyloxycarbonylmethyl, tert-butyloxycarbonylethyl, tert-amyloxycarbonylmethyl and tert-amyloxycarbonylethyl groups. The tert-alkyl group is exemplified by tert-butyl and tert-amyl groups. The cyclic ether group is exemplified by tetrahydropyranyl and tetrahydrofuranyl groups. The alkoxy-alkyl group is exemplified by 1-ethoxyethyl and 1-methoxypropyl groups. The 1-alkyl monocycloalkyl group is exemplified by 1-(lower alkyl) cyclohexyl groups having a cyclic group formed by conjoining of two alkyl groups bonded to the same tertiary carbon atom such as 1-methylcyclohexyl and 1-ethylcyclohexyl groups. The 2-alkyl polycycloalkyl group is exemplified by 2-(lower alkyl) adamantyl groups having a polycyclic hydrocarbon group formed by conjoining of two alkyl groups bonded to the same tertiary carbon atom such as 2-methyladamantyl and 2-ethyladamantyl groups.

A particularly preferable resinous compound as the component (A) is a polyhydroxystyrene or a hydroxystyrene-based copolymer having a weight-average molecular weight of 2000 to 30000 with a molecular weight dispersion not exceeding 6.0, of which 10 to 60% of the hydroxyl hydrogen atoms are substituted by acid-dissociable groups selected from tert-butyloxycarbonyl, tert-butyloxycarbonylmethyl, tert-butyl, tetrahydropyranyl, tetrahydrofuranyl, 1-ethoxyethyl and 1-methoxypropyl groups.

A resinous ingredient particularly suitable as the component (A) in respect of the pattern resolution and cross sectional profile of the patterned resist layer is a combination of (a1) a hydroxystyrene-based copolymer containing 10 to 60% by moles or, preferably, 10 to 50% by moles of tert-butyloxycarbonyloxystyrene units and having a weight-average molecular weight of 2000 to 30000 or, preferably, 5000 to 25000 with a molecular weight dispersion not exceeding 6.0 or, preferably, not exceeding 4.0 and (a2) a hydroxystyrene-based copolymer containing 10 to 60% by moles or, preferably, 10 to 50% by moles of alkoxyalkyloxystyrene units and having a weight-average molecular weight of 2000 to 30000 or, preferably, 5000 to 25000 with a molecular weight dispersion not exceeding 6.0 or, preferably, not exceeding 4.0 in a weight proportion (a1):(a2) of 10:90 to 90:10 or, preferably, 10:90 to 50:50.

Another resinous ingredient also suitable as the component (A) is a combination of (a3) a hydroxystyrene-based copolymer containing 10 to 60% by moles or, preferably, 10 to 50% by moles of tetrahydropyranyloxystyrene units and having a weight-average molecular weight of 2000 to 30000 or, preferably, 5000 to 25000 with a molecular weight dispersion not exceeding 6.0 or, preferably, not exceeding 4.0 and the above described copolymer (a2) in a weight proportion (a3):(a2) of 10:90 to 90:10 or, preferably, 10:90 to 50:50.

A further resinous ingredient also suitable as the component (A) is a combination of (a4) a hydroxystyrene-based copolymer containing 10 to 60% by moles or, preferably, 10 to 50% by moles of tert-butyloxystyrene units and having a weight-average molecular weight of 2000 to 30000 or, preferably, 5000 to 25000 with a molecular weight dispersion not exceeding 6.0 or, preferably, not exceeding 4.0 and the above described copolymer (a2) in a weight proportion (a4):(a2) of 10:90 to 90:10 or, preferably, 10:90 to 50:50.

When the resist composition is a composition of the high-temperature baking type for patterning exposure with KrF excimer laser beams, the resinous compound as the component (A) therein is preferably a copolymer containing (meth)acrylic acid units substituted by acid-dissociable groups for the carboxyl hydrogen atoms and hydroxystyrene units in combination. The acid-dissociable group here can be selected from those given above as the examples, of which tertiary alkyl groups such as tert-butyl groups, 1-(lower alkyl) cyclohexyl groups such as 1-methyl cyclohexyl and 1-ethyl cyclohexyl groups and 2-(lower alkyl) polycycloalkyl groups such as 2-methyladamantyl and 2-ethyladamantyl groups are particularly preferable. An example of the resinous ingredient particularly suitable as the component (A) in respect of the pattern resolution and cross sectional profile and etching resistance of the patterned resist layer is a copolymer having a weight-average molecular weight of 2000 to 30000 or, preferably, 5000 to 25000 with a molecular weight dispersion not exceeding 6.0 or, preferably, not exceeding 4.0 and containing 40 to 80% by moles or, preferably, 50 to 70% by moles of hydroxystyrene units, 10 to 40% by moles or, preferably, 15 to 30% by moles of styrene units and 2 to 30% by moles or, preferably, 5 to 20% by moles of (meth)acrylic acid units substituted by acid-dissociable groups. The hydroxystyrene unit and styrene unit here can be hydroxy-α-methylstyrene unit and α-methylstyrene unit, respectively.

The low temperature-baking photoresist composition mentioned above is a composition of which the photoresist layer before the patterning exposure and after the patterning exposure to light should be subjected to a prebaking treatment and post-exposure baking (PEB) treatment each at a temperature of 90 to 120° C. or, preferably, 90 to 110° C. and the high temperature-baking photoresist composition is a composition of which the prebaking treatment and post-exposure baking treatment are conducted each at a temperature of 110 to 150° C. or, preferably, 120 to 140° C.

The component (B) comprised in the photoresist composition, which is a radiation-sensitive acid-generating compound capable of releasing an acid when irradiated with a radiation such as ultraviolet light, can be selected from the compounds used as an acid-generating agent in the chemical-amplification positive-working photoresist compositions of the prior art without particular limitations as exemplified by diazomethane compounds, nitrobenzyl compounds, sulfonic acid esters, onium salt compounds, benzoin tosylate compounds, halogen-containing triazine compounds and cyano group-containing oximesulfonate compounds, of which diazomethane compounds and onium salt compounds of which the anionic counterpart is a halogenoalkyl sulfonic acid having 1 to 15 carbon atoms are particularly preferable.

Examples of the above-mentioned diazomethane compound include bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane. Examples of the onium salt compound of which the anionic counter part is C1 to C15 halogenoalkyl sulfonic acid include diphenyliodonium trifluoromethanesulfonate and nonafluorobutanesulfonate, bis(4-methoxyphenyl)iodonium trifluoromethanesulfonate and nonafluorobutanesulfonate, bis(4-tert-butylphenyl)iodonium trifluoromethanesulfonate and nonafluorobutanesulfonate, triphenylsulfonium trifluoromethanesulfonate and nonafluorobutanesulfonate, (4-methoxyphenyl)diphenylsulfonium trifluoromethanesulfonate and nonafluorobutanesulfonate and (4-tert-butylphenyl)diphenylsulfonium trifluoromethanesulfonate and nonafluorobutanesulfonate. These acid-generating compounds as the component (B) can be used either singly or as a combination of two kinds or more.

The amount of the component (B) in the photoresist composition is in the range from 1 to 20 parts by weight per 100 parts by weight of the component (A). When the amount of the component (B) is too small, image formation cannot be accomplished by the patternwise light-exposure while, when the amount is too large, the composition can hardly be in the form of a uniform solution due to limited miscibility of the compound or, even if it could ever be obtained, the photoresist solution suffers low storage stability.

The component (C) in the photoresist composition used in the inventive method is a compound to serve as a crosslinking agent for the component (A) so that the compound should have at least two vinyl ether groups or vinyloxy groups in a molecule to work as the crosslinking sites. Namely, a thermal crosslinking reaction proceeds between this crosslinking agent and the resinous compound as the component (A) when a substrate is coated with the photoresist composition followed by heating to give a dried photoresist layer on the substrate surface. Examples of the crosslinking compound as the component (C) are polyhydric alcohols such as alkyleneglycols, polyoxyalkyleneglycols, e.g., dialkyleneglycols and trialkyleneglycols, trimethylolpropane, pentaerithritol and pentaglycol, of which at least two hydroxyl groups in a molecule are substituted by vinyloxy groups. These compounds can be used either singly or as a combination of two kinds or more.

Particular compounds suitable as the component (C) include ethyleneglycol divinyl ether, diethyleneglycol divinyl ether, triethyleneglycol divinyl ether, 1,4-butanediol divinyl ether, tetramethyleneglycol divinyl ether, tetraethyleneglycol divinyl ether, neopentylglycol divinyl ether, trimethylolpropane trivinyl ether, trimethylolethane trivinyl ether, hexanediol divinyl ether, 1,4-cyclohexanediol divinyl ether, pentaerythritol divinyl ether, pentaerythritol trivinyl ether and cyclohexanedimethanol divinyl ether, of which alkyleneglycol divinyl ethers having an alicyclic group such as cyclohexanedimethanol divinyl ether are preferable.

The amount of the component (C) in the photoresist composition is in the range from 0.1 to 25 parts by weight or, preferably, from 1 to 15 parts by weight per 100 parts by weight of the component (A).

The component (D) in the photoresist composition used in the inventive method is an organic amine compound which serves, as a basic compound, to improve stability of the photoresist solution, which may have instability due to the crosslinkability of the component (C). The amine compound as the component (D) is preferably a secondary or tertiary aliphatic amine compound exemplified by dimethylamine, trimethylamine, diethylamine, triethylamine, tri-n-propylamine, triisopropylamine, tri-n-butylamine, triisobutylamine, tri-tert-butylamine, tripentylamine, diethanolamine, triethanolamine and tributanolamine, of which di- and trialkanolamines such as diethanolamine, triethanolamine and tributanolamine are particularly preferable although any of these amine compounds can be used either singly or as a combination of two kinds or more.

The amount of the amine compounds as the component (D) in the photoresist composition is in the range from 0.01 to 1 part by weight or, preferably, from 0.05 to 0.7 part by weight per 100 parts by weight of the component (A).

The positive-working photoresist composition is used in the inventive method in the form of a uniform solution prepared by dissolving the above-described essential components and other optional ingredients in a suitable organic solvent. Examples of suitable organic solvents include ketones such as acetone, methyl ethyl ketone, cyclohexanone, methyl isoamyl ketone and 2-heptanone, polyhydric alcohols and derivatives thereof such as ethyleneglycol, ethyleneglycol monoacetate, diethyleneglycol, diethyleneglycol monoacetate, propyleneglycol, propyleneglycol monoacetate, dipropyleneglycol and dipropyleneglycol monoacetate as well as monomethyl, monoethyl, monopropyl, monobutyl and monophenyl ethers thereof, cyclic ethers such as dioxane and esters such as methyl lactate, ethyl lactate, methyl acetate, ethyl acetate, butyl acetate, methyl pyruvate, ethyl pyruvate, methyl methoxypropionate and ethyl ethoxypropionate, which can be used either singly or as a mixture of two kinds or more.

The photoresist composition can be admixed according to need further with a variety of known additives such as auxiliary resins to improve the film properties of the photoresist layer, plasticizers, stabilizers, coloring agents, surface active agents and others currently under use as an additive in conventional photoresist compositions.

In conducting the method of the invention, it is optional that the substrate surface is provided in advance of step (1) with an antireflection coating film of an inorganic or organic antireflection compound to intervene between the substrate surface and the photoresist layer formed thereon. The antireflection coating film has an effect of improving the pattern resolution of the resist patterning and suppressing the so-called substrate dependency of resist patterning which is a phenomenon that the cross sectional profile of the patterned resist layer is adversely affected as a result of the influence of the nature of the substrate surface on a variety of thin films of SiN, TiN, BPSG and the like formed on the substrate surface. The inorganic antireflection material is exemplified by SiON and several commercial products of organic antireflection coating compositions are available including SWK Series ones (each a product by Tokyo Ohka Kogyo Co.), DUV Series ones (each a product by Brewer Science Co.) and AR Series ones (each a product by Shipley Co.).

Step (1) in the inventive method is for the formation of a positive-working photoresist layer on the substrate surface and can be performed according to a known procedure undertaken in the prior art. Namely, a substrate such as a semiconductor silicon wafer, which may be provided with an antireflection coating film thereon, is coated with the photoresist solution by using a suitable coating machine such as a spinner followed by drying to form a photoresist layer on the substrate surface. In step (2), the thus formed photoresist layer is patternwise exposed to light through a halftone phase-shift photomask followed by a post-exposure baking treatment to form a latent image of the pattern in the photoresist layer. In step (3), the photoresist layer is subjected to a development treatment by using an aqueous alkaline developer solution such as a 0.1 to 10% by weight aqueous solution of tetramethylammonium hydroxide to give a patterned resist layer. In step (4), the patterned resist layer is subjected to a heat treatment to cause thermal flow of the resist layer resulting in reduction of the pattern size as compared with the size of the pattern just as developed. This heat treatment for thermal flow is undertaken under control to accomplish a size reduction of the resist pattern not exceeding 15 nm or, preferably, in the range from 2 to 10 nm per unit temperature.

In order to accomplish the controlled thermal flow of the patterned resist layer as mentioned above, it is preferable that the coating layer of the photoresist solution is dried to form a dried resist layer by heating at a temperature in the range from 80 to 150° C. for 30 to 120 seconds.

The post-exposure baking treatment of the patternwise exposed photoresist layer is conducted by heating on a hot plate at 90 to 150° C. for 30 to 120 seconds. The heat treatment to cause size-reducing thermal flow of the patterned resist layer after development is conducted on a hot plate at 110 to 180° C. for 30 to 180 seconds.

When a hole pattern of a resist layer is formed by the photolithography using a halftone phase-shift photomask according to the present invention, occurrence of dimples, which unavoidably accompany the use of a halftone phase-shift photomask, can greatly be suppressed by adequately controlling the pattern size reduction as a consequence of thermal flow of the resist layer.

In the following, the method of the present invention is described in more detail by way of examples, in which the term of “parts” always refers to “parts by weight”. In the Examples described below, evaluation tests were undertaken for the following items by the testing procedures respectively given there.

(1) Sensitivity of the Photoresist Composition

A 0.5 μm thick positive-working photoresist layer formed on a substrate surface was exposed to KrF excimer laser beams through a halftone phase-shift photomask on a minifying projection exposure machine (Model FPA-3000EX3, manufactured by Canon Co.) in stepwise increased exposure doses with 1 mJ/cm² increments and, after a post-exposure baking treatment at 110° C. for 90 seconds, subjected to a development treatment at 23° C. for 60 seconds with a 2.38% aqueous solution of tetramethylammonium hydroxide followed by water rinse for 30 seconds and drying. The thickness of the thus formed resist layers by development was determined and the minimum exposure dose with which the resist layer had been completely dissolved away by development was recorded as the sensitivity of the photoresist composition.

(2) Resist Pattern Profile

A resist hole pattern of 0.25 μm diameter obtained by the same procedure as (1) above was examined on a scanning electron microscopic photograph for the hole pattern profile and occurrence of dimples. The results were recorded in two ratings of A and B when the hole was straight down to the substrate surface and when the hole was tapered apparently narrowing toward the substrate surface, respectively.

(3) Pattern Resolution

The critical pattern resolution was determined for hole-patterned resist layers.

(4) Thermal Flow Characteristics

A hole-patterned resist layer of 0.20 μm hole diameter was subjected to a heat treatment until the hole diameter was reduced to 0.15 μm and the flow rate, i.e. resist pattern size reduction per degree centigrade, was calculated. The results were recorded in three ratings of A, B and C for the flow rate not exceeding 5 nm/° C., in the range of 5 to 15 nm/° C. and exceeding 15 nm/° C., respectively.

The influence of thickness of the resist layer has a relatively small influence on the result of this test so that the thickness should be smaller than 1.0 μm or, preferably, in the range from 0.4 to 0.85 μm. When the thickness is small enough, an improvement can be obtained in the pattern resolution and a thermal flow rate of 2 to 15 nm/° C. can be accomplished as a trend.

### EXAMPLE 1

A positive-working photoresist composition was prepared by dissolving, in 490 parts of propyleneglycol monomethyl ether acetate, a combination of 75 parts of a first polyhydroxystyrene resin having a weight-average molecular weight of 10000 with a molecular weight dispersion of 1.2, of which 39% of the hydroxyl hydrogen atoms were substituted by 1-ethoxyethyl groups, and 25 parts of a second polyhydroxystyrene resin having a weight-average molecular weight of 10000 with a molecular weight dispersion of 1.2, of which 36% of the hydroxyl hydrogen atoms were substituted by tert-butyloxycarbonyl groups, 5 parts of bis(cyclohexylsulfonyl) diazomethane, 5 parts of 1,4-cyclohexanedimethanol divinyl ether, 0.2 part of triethanolamine and 0.05 part of a fluorosilicone-based surface active agent to give a solution which was filtered through a membrane filter of 0.2 μm pore diameter.

A semiconductor silicon wafer of 200 mm diameter and 0.72 mm thickness provided in advance with an antireflection coating film of 0.12 nm thickness by using an antireflection coating solution (SWK-EX2, a product by Tokyo Ohka Kogyo Co.) was coated by using a spinner with the above prepared photoresist solution followed by heating on a hot plate at 90° C. for 90 seconds to form a dried photoresist layer having a thickness of 0.5 μm.

The thus formed photoresist layer was subjected to the evaluation tests for the sensitivity, cross sectional profile and pattern resolution by the testing procedures described above to give the results shown in Table 1 below. Separately, the photoresist layer formed on the substrate surface was exposed to KrF excimer laser beams through a halftone phase-shift photomask on the exposure machine (supra) and, after a post-exposure baking treatment at 110° C. for 90 seconds, subjected to a development treatment at 23° C. for 60 seconds with a 2.38% aqueous solution of tetramethylammonium hydroxide followed by water rinse for 30 seconds and drying to give a patterned resist layer having a hole pattern of 0.20 μm diameter.

The silicon wafer bearing the thus formed hole-patterned resist layer of 0.20 μm diameter was mounted and heated on a hot plate at 145° C. for 90 seconds until the diameter of the hole pattern was reduced to 0.15 μm to give a reduced-size resist hole pattern, of which the result of the evaluation test for the thermal flow treatment is shown in Table 1 below.

### EXAMPLE 2

The experimental procedure was substantially the same as in Example 1 except that the positive-working photoresist solution was prepared by replacing the combination of 75 parts and 25 parts of the first and second, respectively, polyhydroxystyrene resins with 100 parts of the first polyhydroxystyrene resin alone and the heating temperature for the thermal flow treatment was 135° C. instead of 145° C. The results of the evaluation tests are shown in Table 1 below.

### EXAMPLE 3

The experimental procedure was substantially the same as in Example 1 except that the positive-working photoresist solution was prepared by replacing the combination of 75 parts and 25 parts of the first and second, respectively, polyhydroxystyrene resins with a combination of 70 parts of the first polyhydroxystyrene resin and 30 parts of a third polyhydroxystyrene resin having a weight-average molecular weight of 10000 with a molecular weight dispersion of 1.2, of which 30% of the hydroxyl hydrogen atoms were substituted by tetrahydropyranyl groups, and the heating temperature for the thermal flow treatment was 140 ° C. instead of 145° C. The results of the evaluation tests are shown in Table 1 below.

### EXAMPLE 4

The experimental procedure was substantially the same as in Example 1 except that the positive-working photoresist solution was prepared by replacing the combination of 75 parts and 25 parts of the first and second, respectively, polyhydroxystyrene resins with a combination of 75 parts of the first polyhydroxystyrene resin and 25 parts of a fourth polyhydroxystyrene resin having a weight-average molecular weight of 10000 with a molecular weight dispersion of 1.2, of which 30% of the hydroxyl hydrogen atoms were substituted by tert-butyl groups, and the heating temperature for the thermal flow treatment was 150° C. instead of 145° C. The results of the evaluation tests are shown in Table 1 below.

### EXAMPLE 5

The experimental procedure was substantially the same as in Example 1 except that the positive-working photoresist solution was prepared by replacing the combination of 75 parts and 25 parts of the first and second, respectively, polyhydroxystyrene resins with a combination of 60 parts of a first copolymeric resin of 65% by moles of hydroxystyrene, 20% by moles of styrene and 15% by moles of tert-butyl acrylate having a weight-average molecular weight of 10000 and 40 parts of a second copolymeric resin of 75% by moles of hydroxystyrene, 20% by moles of styrene and 5% by moles of tert-butyl acrylate having a weight-average molecular weight of 10000 and the heating temperature for the thermal flow treatment was 170° C. instead of 145° C. The results of the evaluation tests are shown in Table 1 below.

### EXAMPLE 6

The experimental procedure was substantially the same as in Example 1 except that, in the formulation of the positive-working photoresist solution, the triethanolamine was replaced with the same amount of tributylamine and the amount of the 1,4-cyclohexanedimethanol divinyl ether was decreased from 5 parts to 2.5 parts and the heating temperature for the thermal flow treatment was 135° C. instead of 145° C. The results of the evaluation tests are shown in Table 1 below.

### COMPARATIVE EXAMPLE 1

The experimental procedure was substantially the same as in Example 1 except that the positive-working photoresist solution was prepared by omitting the 1,4-cyclohexanedimethanol divinyl ether in the formulation and the heating temperature for the thermal flow treatment was 130° C. instead of 145° C. The results of the evaluation tests are shown in Table 1 below, which indicates that absolutely no size reduction of the resist hole pattern could be accomplished.

TABLE 1

| | | | | Pattern | Thermal |
|---|---|---|---|---|---|
| | Sensi- | Resist | | resolu- | flow |
| | tivity, | pattern | | tion, | charac- |
| | mJ/cm² | profile | Dimples | μm | teristics |
| Example 1 | 40 | A | no | 0.18 | A |
| Example 2 | 35 | A | no | 0.17 | B |
| Example 3 | 42 | A | no | 0.18 | A |
| Example 4 | 44 | A | no | 0.18 | A |
| Example 5 | 30 | A | no | 0.18 | A |
| Example 6 | 37 | B | a little | 0.18 | B |
| | | | but | | |
| | | | accept- | | |
| | | | able | | |
| Comparative | 35 | A | no | 0.18 | C |
| Example 1 | | | | | |

What is claimed is:

1. A method for the formation of a fine resist hole pattern on a substrate surface in a photolithographic patterning process by using a halftone phase-shift photomask, which comprises the steps of:
(1) forming a photoresist layer on the substrate surface by using a positive-working photoresist composition comprising
(A) 100 parts by weight of a resinous compound capable of being imparted with increased solubility in an aqueous alkaline solution by interacting with an acid, (B) from 1 to 20 parts by weight of a compound capable of generating an acid by irradiation with a radiation, (C) from 0.1 to 25 parts by weight of a compound having, in a molecule, at least two vinyloxy groups which react with the component (A) to form crosslinks, and (D) from 0.01 to 1 part by weight of an organic amine compound;
(2) patternwise exposing the photoresist layer to light through a halftone phase-shift photomask;
(3) developing the photoresist layer to form a patterned resist layer; and
(4) subjecting the patterned resist layer to a heat treatment to cause reduction of the resist pattern size by thermal flow.

2. The method as claimed in claim 1 in which the heat treatment in step (4) is conducted at a temperature in the range from 110 to 180° C. for 30 to 180 seconds.

3. The method as claimed in claim 1 in which the component (C) is a polyhydric alcohol substituted by vinyloxy groups for the hydrogen atoms of at least two hydroxyl groups in a molecule.

4. The method as claimed in claim 3 in which the component (C) is cyclohexanedimethanol divinyl ether.

5. A positive-working photoresist composition which comprises, as a uniform solution in an organic solvent;
(A) 100 parts by weight of a resinous compound capable of being imparted with increased solubility in an aqueous alkaline solution by interacting with an acid;
(B) from 1 to 20 parts by weight of a compound capable of generating an acid by irradiation with a radiation;
(C) from 0.1 to 25 parts by weight of a compound having, in a molecule, at least two vinyloxy groups which react with the component (A) to form crosslinks; and
(D) from 0.01 to 1 part by weight of an organic amine compound.

6. The composition as claimed in claim 5 in which the component (A) is a polyhydroxystyrene resin having a weight-average molecular weight in the range from 2000 to 30000 with a molecular weight dispersion not exceeding 6.0, of which from 10 to 60% of the hydroxyl hydrogen atoms are substituted by acid-dissociable groups selected from the group consisting of tert-butyloxycarbonyl, tert-butyloxycarbonylmethyl, tert-butyl, tetrahydropyranyl, tetrahydrofuranyl, 1-ethoxyethyl and 1-methoxypropyl groups.

7. The composition as claimed in claim 5 in which the component (A) is a combination of (al) a hydroxystyrene-based copolymer containing, as a part of the monomeric units, 10 to 60% by moles of tert-butyloxycarbonyloxystyrene units and having a weight-average molecular weight of 2000 to 30000 with a molecular weight dispersion not exceeding 6.0 and (a2) a hydroxystyrene-based copolymer containing, as a part of the monomeric units, 10 to 60% by moles of alkoxyalkyloxystyrene units and having a weight-average molecular weight of 2000 to 30000 with a molecular weight dispersion not exceeding 6.0 in a weight proportion in the range from 90:10 to 10:90.

8. The composition as claimed in claim 5 in which the component (A) is a combination of (a3) a hydroxystyrene-based copolymer containing, as a part of the monomeric units, 10 to 60% by moles of tetrahydropyranyloxystyrene units and having a weight-average molecular weight of 2000 to 30000 with a molecular weight dispersion not exceeding 6.0 and (a2) a hydroxystyrene-based copolymer containing, as a part of the monomeric units, 10 to 60% by moles of alkoxyalkyloxystyrene units and having a weight-average molecular weight of 2000 to 30000 with a molecular weight dispersion not exceeding 6.0 in a weight proportion in the range from 90:10 to 10:90.

9. The composition as claimed in claim 5 in which the component (A) is a combination of (a4) a hydroxystyrene-based copolymer containing, as a part of the monomeric units, 10 to 60% by moles of tert-butyloxystyrene units and having a weight-average molecular weight of 2000 to 30000 with a molecular weight dispersion not exceeding 6.0 and (a2) a hydroxystyrene-based copolymer containing, as a part of the monomeric units, 10 to 60% by moles of alkoxyalkyloxystyrene units and having a weight-average molecular weight of 2000 to 30000 with a molecular weight dispersion not exceeding 6.0 in a weight proportion in the range from 90:10 to 10:90.

10. The composition as claimed in claim 5 in which the component (A) is a copolymer consisting of hydroxystyrene units and acrylic or methacrylic acid units, of which the carboxyl hydrogen atoms in the acrylic or methacrylic acid units are substituted by acid-dissociable groups selected from the group consisting of tert-alkyl groups, 1-alkylcyclohexyl groups, 2-alkylcyclohexyl groups and 2-alkyl polycycloalkyl groups.

11. The composition as claimed in claim 5 in which the component (A) is a copolymer having a weight-average molecular weight in the range from 2000 to 30000 with a molecular weight dispersion not exceeding 6.0 and consisting of 40 to 80% by moles of hydroxystyrene units, 10 to 40% by moles of styrene units and 2 to 30% by moles of acrylic or methacrylic acid units substituted for the carboxyl hydrogen atoms by acid-dissociable groups.

12. The composition as claimed in claim 5 in which the component (C) is a compound selected from the group consisting of polyhydric alcohols substituted by at least two vinyloxy groups in a molecule.

13. The composition as claimed in claim 12 in which the component (C) is a divinyl ether of an alkyleneglycol having an alicyclic ring structure in the molecule.

14. The composition as claimed in claim 13 in which the component (C) is cyclohexanedimethanol divinyl ether.

15. The composition as claimed in claim 5 in which the component (D) is an amine compound selected from the group consisting of secondary aliphatic amines and tertiary aliphatic amines.

16. The composition as claimed in claim 15 in which the component (D) is selected from the group consisting of dimethylamine, trimethylamine, diethylamine, triethylamine, tri-n-propylamine, triisopropylamine, tri-n-butylamine, triisobutylamine, tri-tert-butylamine, tripentylamine, diethanolamine, triethanolamine and tributanolamine.

17. The composition as claimed in claim 16 in which the component (D) is diethanolamine, triethanolamine or tributanolamine.
